(19) United States
(12) Patent Application Publication
(10) Pub. No.: US 2008/0094790 A1
(43) Pub. Date: Apr. 24, 2008

(54) Plasma display device

(76) Inventor: Keun-Young Song, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/907,582

(22) Filed: Oct. 15, 2007

(30) Foreign Application Priority Data
Oct. 19, 2006 (KR) 10-2006-0101947

(51) Int. Cl. H05K 5/00

(52) U.S. Cl. 361/681

(57) ABSTRACT

A plasma display device includes a plasma display panel (PDP), a chassis base on the PDP, a plurality of printed circuit board assemblies (PBAs) on the chassis base and electrically connected to the PDP, at least one of the PBAs including a single-sided board with a plurality of insert-holes for electrical connection, and at least one circuit element with a plurality of leads adapted to be respectively inserted into the plurality of insert-holes of the single-sided board, wherein the single-sided board includes a plurality of slots between the insert-holes.

### BACKGROUND OF THE INVENTION

1. Field of the Invention

Embodiments of the present invention relate to a plasma display device. More particularly, embodiments of the present invention relate to a plasma display device with an improved structure of a circuit element on a printed circuit board assembly of the plasma display device.

2. Description of the Related Art

In general, a plasma display device refers to a flat display device having a plasma display panel (PDP) operated via a discharge phenomenon. More specifically, vacuum ultra violet (VUV) light may be emitted from plasma generated by an application of voltage to a discharge gas, thereby exciting a photoluminescent material to emit visible light. The excited photoluminescent material may generate red (R), green (G), and/or blue (B) visible light to form images.

A shape of a waveform of a driving voltage and/or a discharge cell structure may classify the PDP into a DC-type PDP and/or an AC-type PDP. For example, the conventional AC-type PDP may include address electrodes on a rear substrate and display electrodes including pairs of sustain and scan electrodes on a front substrate facing the rear substrate. Barrier ribs may be formed between the rear and front substrates to define discharge cells, while the discharge cells may be filled with discharge gas. More than millions of unit discharge cells may be arranged in the PDP in a matrix pattern.

The PDP may include a plurality of printed circuit board assemblies (PBAs) to control the sustain, scan, and address electrodes through a plurality of circuits, e.g., printed circuit boards (PCBs), and connectors. More specifically, the PBAs may include a plurality of circuit boards with circuit elements thereon, e.g., load driving circuits that directly drive and load circuits and signal circuits that implement an oscillation signal or an interrupt signal required for driving various loads. The circuit elements may be connected to a respective circuit board via leads inserted into insert-holes in the circuit board. A number of leads in each circuit element may depend on the type of circuit and/or weight of the circuit element, e.g., a larger number of leads may be required for heavier elements requiring a high current.

However, when the circuit board is a single-sided board, i.e., a board having a copper foil pattern made of a conductive material only on one side thereof, a space thereon for circuit elements' leads may be limited, and may require reduced gaps between the circuit elements' leads. Reduced gaps between leads may cause some of the leads to interconnect, e.g., during soldering, thereby triggering electrical short therebetween.

### SUMMARY OF THE INVENTION

The present invention is therefore directed to a plasma display device, which substantially overcomes one or more of the problems due to the limitations and disadvantages of the related art.

It is therefore a feature of an embodiment of the present invention to provide a plasma display device having an improved structure of a circuit element with a plurality of leads on a single-side circuit board of a printed circuit board assembly.

At least one of the above and other features of the present invention may be realized providing a plasma display device including a plasma display panel (PDP), a chassis base on the PDP, a plurality of printed circuit board assemblies (PBAs) on the chassis base and electrically connected to the PDP, at least one of the PBAs including a single-sided board with a plurality of insert-holes for electrical connection, and at least one circuit element with a plurality of leads adapted to be respectively inserted into the plurality of insert-holes of the single-sided board, wherein the single-sided board includes a plurality of slots between the insert-holes. The circuit element may be a switching element. The PBAs may include an address buffer board, a scan electrode driving board, a sustain electrode driving board, an image board, and/or a power supply board.

Each slot may be positioned between two adjacent insert-holes. The slots may be spaced at equal intervals. The slots may penetrate the single-sided board from one surface to an opposite surface. Each slot may be longer than a diameter of the insert-hole. The single-sided board may include a ground around each insert-hole. A length of each slot may substantially equal an outer width of the ground. Each slot may be between two adjacent grounds. A width of each slot may substantially equal a distance between two adjacent grounds.

The plasma display device may further include a fixing member along an inner surface of each insert-hole. The fixing member may be a cylinder-shaped eyelet. The fixing member may include a rim. An outer diameter of the rim may be longer than a diameter of the insert-hole. The fixing member may have a height that substantially equals to or shorter than a height of the single-sided board.

The plasma display may further include a bonding material in the inset hole and in communication with the fixing member. The bonding material may completely fill any space in the insert-hole not occupied by the fixing member or the lead. The bonding material may be on upper and lower surfaces of the single-sided board. The bonding material may be a conductive material. The bonding material may be a solder paste.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a perspective view of a plasma display device according to an embodiment of the present invention;

FIG. 2 illustrates a perspective view of a circuit element on a single-sided circuit board of the plasma display device of FIG. 1;

FIG. 3 illustrates an exploded cross sectional view of a circuit element on a single-sided circuit board according to an embodiment of the present invention;

FIG. 4 illustrates an assembled cross sectional view of the circuit element of FIG. 3; and

FIG. 5 illustrates a schematic view of structural configuration between insert-holes, grounds, and slots on a single-sided board according to an embodiment of the present invention.

### DETAILED DESCRIPTION OF THE INVENTION

Korean Patent Application No. 10-2006-0101947, filed on Oct. 19, 2006, in the Korean Intellectual Property Office, and entitled: “Plasma Display Device,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art. For clear understanding, irrelevant descriptions will be omitted.

In the figures, the dimensions of layers and regions may be exaggerated for clarity of illustration. It will also be understood that when a layer or element is referred to as being “on” another layer or substrate, it can be directly on the other layer or substrate, or intervening layers or elements may also be present. Further, it will be understood that when a layer or element is referred to as being “under” another layer, it can be directly under, or one or more intervening layers or elements may also be present. In addition, it will also be understood that when a layer is referred to as being “between” two layers, it can be the only layer between the two layers, or one or more intervening layers or elements may also be present. Like reference numerals refer to like elements throughout.

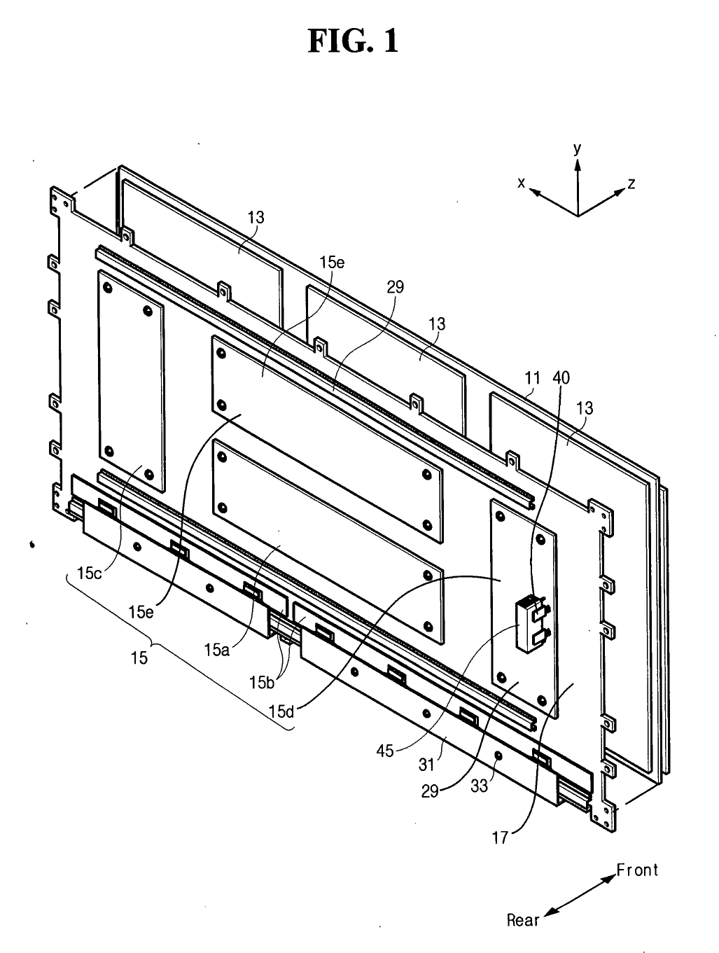

An exemplary embodiment of a plasma display device according to the present invention will be described in more detail below with reference to FIG. 1. As illustrated in FIG. 1, a plasma display device may include a plasma display panel (PDP) 11, a chassis base 17 on a rear surface of the PDP 11, at least one thermal conductive sheet 13 between the PDP 11 and the chassis base 17, a plurality of printed circuit board assemblies (PBAs) 15 on the chassis base 17, and a plurality of circuit elements 40 connected to the PBAs 15.

The PDP 11 of the plasma display device may include front and rear substrates integrally bonded to each other by means of a sealant. Discharge cells (not shown) filled with discharge gas may be formed between the front and rear substrates to facilitate visible light emission upon plasma generation. The PDP 11 may use the gas discharge to display images. The PDP 11 may be any suitable PDP.

The chassis base 17 of the plasma display device may be a thin metal plate formed by, e.g., die-casting or press process, and may be attached to the rear substrate of the PDP 11. A central portion of the chassis base 17 may be curved, e.g., convex along the z-axis with respect to the PDP 11, to increase mechanical rigidity thereof, i.e., facilitate absorption of strain and bending force. Alternatively, at least one reinforcement member 29 may be provided on a rear surface of the chassis base 17, e.g., a thin longitudinal member along the x-axis in upper and/or lower horizontal portions of the chassis base 17, and adjacent to the PBAs 15, as illustrated in FIG. 1. The chassis base 17 may further include a cover plate 31 in a lower portion thereof, as further illustrated in FIG. 1.

The PBAs 15 of the plasma display device may be arranged on the rear surface of the chassis base 17, and may be electrically connected to the PDP 11. The PBAs 15 may include an image board 15a, an address buffer board 15b, a scan electrode driving board 15c, a sustain electrode driving board 15d, and a power supply board 15e. The image board 15a may generate control signals for driving address, sustain, and scan electrodes (not shown), and supply the generated control signals to the address buffer board 15b, the sustain electrode driving board 15d, and the scan electrode driving board 15c. The address buffer board 15b may control the address electrodes. The scan electrode driving board 15c may control the scan electrodes. The sustain electrode driving board 15d may control the sustain electrodes. The power supply board 15e may supply power for driving the PBAs 15.

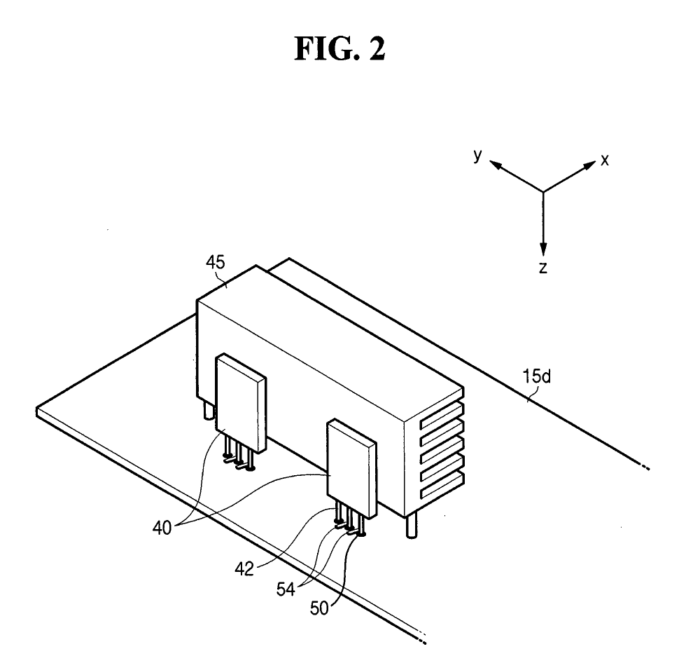

The PBAs 15 may include at least one single-sided circuit board (not shown). In this respect, it should be noted that a “single-sided board” may refer to all or a part of either of the PBAs 15 having a conductive pattern, e.g., a copper foil pattern, of an electrical circuit only on one surface of a respective PBA 15. As illustrated in FIG. 2, the single-sided circuit board, e.g., the sustain electrode driving board 15d, may include a plurality of insert-holes 50 to facilitate electrical connection of the circuit element 40 thereto via a plurality of leads 42 inserted into the insert-holes 50. The insert-holes 50 may be through-holes. It is noted that the circuit element 40 mounted on the single-sided board of the sustain electrode driving board 15d is used for illustration purpose only, and any number of circuit elements 40 may be mounted on either PBA 15, as may be determined by one of ordinary skill in the art. Accordingly, it is further noted that hereinafter the terms “single-sided board” and “sustain electrode driving board 15d” may be used interchangeably without for illustration only and not for purpose of limitation.

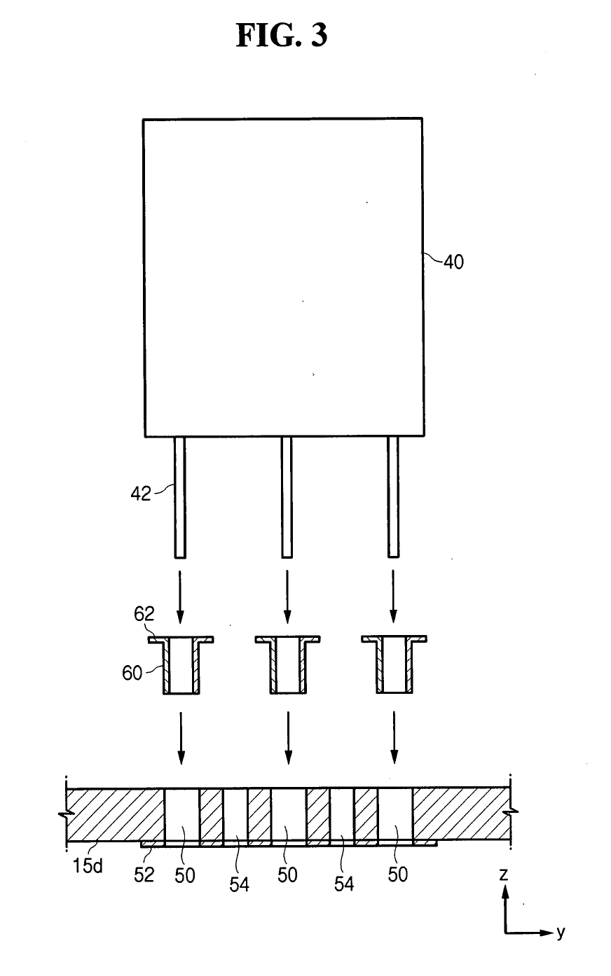

The circuit element 40 may be a relatively heavy element or an insertion component, e.g., a heat-generating component. For example, the circuit element 40 may be a switching element with a plurality of leads 42 or an insulated gate bipolar transistor (IGBT) having three leads 42 on the sustain electrode driving board 15d. Each circuit element 40 may include a heat sink 45, as illustrated in FIG. 2, and may be surrounded by a ground 52 upon insertion into the insert-hole 50, as illustrated in FIGS. 3-5. A slot 54 may be formed between every two insert-holes 50, as further illustrated in FIG. 2. A structural relationship between each of the leads 40, grounds 52, insert-holes 50, and slots 54 will be discussed in more detail below with respect to FIGS. 3-5.

The circuit element 40 may generate heat upon application of a sustain pulse to the sustain electrodes of the sustain electrode driving board 15d. The generated heat may be dissipated by the heat sink 45 attached to a lateral portion of the circuit element 40, thereby avoiding erroneous operations. Ends of the heat sink 45 may have no contact with the sustain electrode driving board 15d, as illustrated in FIG. 2, to minimize contact therewith, so that the heat sink 45 may maintain a floating state. In order to avoid interference with the pattern of the single-sided board, the heat sink 45 may be attached to the circuit element 40 above a portion of the single-sided board having no electrical patterns.

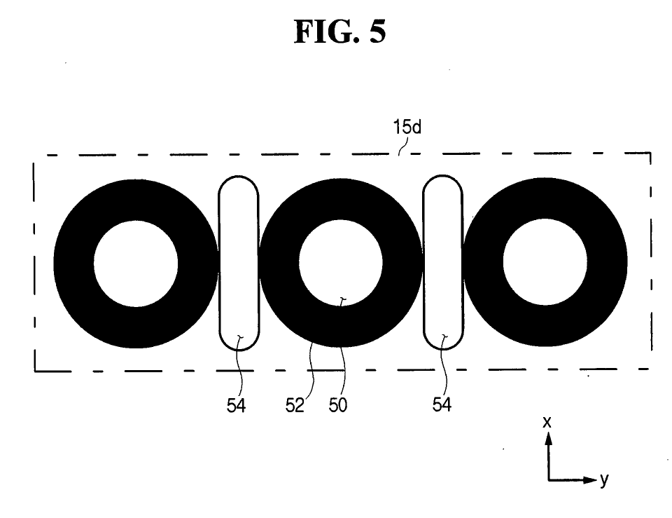

The ground 52 may be formed on the sustain electrode driving board 15d around the insert-holes 50 by, e.g., a plating method, to facilitate electrical connection of circuit wires, i.e., the pattern, to the circuit element 40. The ground 52 may be formed on a same surface as the pattern, and may have a shape corresponding to a shape of the insert-holes 50, e.g., a circular or a polygonal structure surrounding the insert-holes 50. For example, a planar cross section of the ground 52, i.e., in the xy-plane, may have a circular or a polygonal ring structure, so that the ground 52 may have inner and outer widths, as illustrated in FIG. 5. The insert-hole 50 may be co-centric with the ground 52. Accordingly, the inner width of the ground 52 may substantially equal a diameter of the insert-hole 50, i.e., the inner width of the ground 52 and an outer circumference of the insert-hole 50 may be coextensive, as further illustrated in FIG. 5. If the ground 52 is circular, the width thereof may be a diameter.

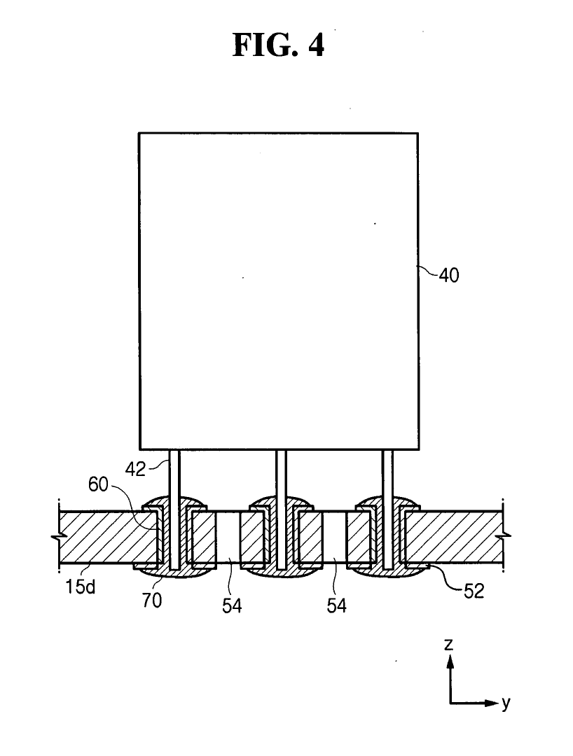

The slots 54 may be formed between the insert-holes 50. More specifically, one slot 54 may be positioned between every two insert-holes 50, as illustrated in FIG. 5. The slots 54 may be formed through the single-sided board, i.e., extend entirely through the single-sided board to contact an exterior through upper and lower surfaces of the single-sided board. In other words a height of each slot along the z-axis may substantially equal a height of the single-sided board, as illustrated in FIGS. 3-4. A length of the slot 54, i.e., a distance as measured along the x-axis, may be greater than the diameter of the insert-hole 50, and may be substantially equal to the outer width of the ground 52. The slots 54 may be formed at equal intervals between the grounds 52, so a width of the slot 54, i.e., a distance as measured along the y-axis, may equal, e.g., a distance between two outer perimeters of adjacent grounds 52. However, other configurations pf the slots 54, e.g., the slots 54 may not be in communication with the grounds 52, are within the scope of the present invention. Formation of slots 54 between the grounds 52 may be advantageous in preventing an electrical connection therebetween. Further, such formation may enable formation of wider grounds 52 and may minimize a potential electrical short between the leads 42 of the circuit element 40.

As illustrated in FIGS. 3-4, the circuit element 40 may be mounted on the single-sided board via the leads 42, a fixing member 60, and a bonding material 70. More specifically, the fixing member 60 may be provided along inner surfaces of the insert-hole 50, i.e., positioned between the inner surfaces of the insert-hole 50 and the inserted lead 42. Upon insertion of the lead 42 of the circuit element 40 into the insert-hole 50, the bonding material 70 may be deposited in the insert-hole 50 between the fixing member 60 and the lead 42 to connect the fixing member 60 to the circuit element 40.

The fixing member 60 may have a shape corresponding to a shape of the insert-hole 50. For example, the fixing member 60 may be an eyelet having a cylindrical shape and a rim 62, as illustrated in FIG. 3, so that the eyelet may be inserted into the insert-hole 50, and the rim 62 may be positioned on an upper surface of the sustain electrode driving board 15d. A height of the fixing member 60 may substantially equal the height of the sustain electrode driving board 15d. For example, upon insertion of the fixing member 60 into the insert-hole 50 and positioning the rim 62 on the upper surface of the sustain electrode driving board 15d, a lower end of the fixing member 60, i.e. an end opposite the rim 62, may not protrude through the insert-hole 50.

The rim 62 may surround one end of the fixing member 60, and may protrude outwardly therefrom. For example, the rim 62 may be perpendicular to the fixing member 60, and may have a ring structure surrounding the insert-hole 50, as illustrated in FIGS. 3-4. A length, i.e., a distance as measured along the y-axis between two outer-most ends of the rim 62, may be greater than the diameter of the insert-hole 50. In this respect, it is noted that the two outer-most ends of the rim 62 may be two opposite points on an outer perimeter of the rim 62, e.g., an outer diameter of the rim 62. An inner diameter of the rim 62 may be substantially equal to the diameter of the insert-hole 50. Accordingly, if the rim 62 of the fixing member 60 is longer than the diameter of the insert-hole 50, the fixing member 60 may be secured along inner surfaces of the insert-hole 50. Moreover, since the height of the fixing member 60 is substantially equal to the height of the single-sided board, an operation for punching an end portion of the fixing member 60 to outwardly unfold the fixing member 60 may be unnecessary.

Upon insertion of the fixing member 60 into the insert-hole 50, a first gap may be formed between an outer circumferential surface of the fixing member 60 and the insert-hole 50. Further, a second gap may be formed between an inner circumferential surface of the fixing member 60 and the lead 42 of the circuit element 40. The bonding material 70, e.g., a solder paste, may be deposited into the first and second gaps to increase connection therebetween. More specifically, the bonding material 70 may be deposited in the insert-hole 50 after insertion of the lead 42, followed by a reflow process. The bonding material 70 may increase mechanical and electrical bonding between the circuit element 40 and the single-sided board.

A method of fixing the lead 42 of the circuit element 40 to the single-sided board according to an embodiment of the present invention will now be described with reference to FIGS. 3 to 5.

First, the fixing member 60 may be inserted into the insert-hole 50 of the single-sided board, so the rim 62 may be positioned on an upper surface of the single-sided board. Thereafter, the lead 42 of the circuit element 40 may be inserted into the insert-hole 50, so the fixing member 60 may be positioned between the lead 42 and the inner surfaces of the insert-hole 50. For example, the lead 42 may be centered in the insert-hole 50. In this respect, it is noted that the sustain electrode driving board 15d may be positioned between the rim 62 of the fixing member 60 and the ground 52, as illustrated in FIGS. 3-4.

Next, a solder paste may be deposited in the insert-hole 50. More specifically, the solder paste may be deposited between the fixing member 60 and the lead 42 of the circuit element 40. Thereafter, the single-sided board may be subject to the reflow process to convert the solder paste into the bonding material 70. In the reflow process, the solder paste may flow into the first gap between the outer circumferential surface of the fixing member 60 and the insert-hole 50 to bond therebetween. Furthermore, the solder paste may bond the second gap between the inner circumferential surface of the fixing member 60 and the lead 42 of the circuit element 40 to increase the bonding state of the circuit element 40.

Formation of the PBAs 15 of the plasma display device according to embodiments of the present invention may be advantageous in providing improved electrical and structural stability of the circuit element 40 in the PBA 15 via the fixing member 60 and the bonding material 70 in the insert-hole 50. Further, the structure of the PBA 15 provides wider grounds 52 and minimized electrical shorts between adjacent leads 42 of the circuit element 40 due to slots 54 therebetween.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A plasma display device, comprising:
a plasma display panel (PDP);
a chassis base on the PDP;
a plurality of printed circuit board assemblies (PBAs) on the chassis base and electrically connected to the PDP, at least one of the PBAs including a single-sided board with a plurality of insert-holes for electrical connection; and
at least one circuit element with a plurality of leads adapted to be respectively inserted into the plurality of insert-holes of the single-sided board,
wherein the single-sided board includes a plurality of slots between the insert-holes.

2. The plasma display device as claimed in claim 1, wherein each slot is positioned between two adjacent insert-holes.

3. The plasma display device as claimed in claim 1, wherein the slots are spaced at equal intervals.

4. The plasma display device as claimed in claim 1, wherein the slots penetrate the single-sided board from one surface to an opposite surface.

5. The plasma display device as claimed in claim 1, wherein each slot is longer than a diameter of the insert-hole.

6. The plasma display device as claimed in claim 1, wherein the single-sided board includes a ground around each insert-hole.

7. The plasma display device as claimed in claim 6, wherein each slot is between two adjacent grounds.

8. The plasma display device as claimed in claim 7, wherein a width of each slot substantially equals a distance between two adjacent grounds.

9. The plasma display device as claimed in claim 6, wherein a length of each slot substantially equals an outer width of the ground.

10. The plasma display device as claimed in claim 1, further comprising a fixing member along an inner surface of each insert-hole.

11. The plasma display device as claimed in claim 10, wherein the fixing member is a cylinder-shaped eyelet.

12. The plasma display device as claimed in claim 10, wherein the fixing member includes a rim.

13. The plasma display device as claimed in claim 12, wherein an outer diameter of the rim is longer than a diameter of the insert-hole.

14. The plasma display device as claimed in claim 10, wherein the fixing member has a height that substantially equals to or shorter than a height of the single-sided board.

15. The plasma display device as claimed in claim 10, further comprising a bonding material in the inset hole and in communication with the fixing member.

16. The plasma display device as claimed in claim 15, wherein the bonding material completely fills any space in the insert-hole not occupied by the fixing member or the lead.

17. The plasma display device as claimed in claim 15, wherein the bonding material is a conductive material.

18. The plasma display device as claimed in claim 15, wherein the bonding material is a solder paste.

19. The plasma display device as claimed in claim 1, wherein the circuit element is a switching element.

20. The plasma display device as claimed in claim 1, wherein the PBAs include an address buffer board, a scan electrode driving board, a sustain electrode driving board, an image board, and/or a power supply board.
